(19) United States
(12) Patent Application Publication
(10) Pub. No.: US 2023/0180553 A1
(43) Pub. Date: Jun. 8, 2023

(54) DISPLAY DEVICE

(71) Applicant: LG Display Co., Ltd., Seoul (KR)

(72) Inventors: MoonSoo KIM, Paju-si (KR); Saemleenuri LEE, Paju-si (KR); Sungbai Lee, Paju-si (KR)

(21) Appl. No.: 17/970,398

(22) Filed: Oct. 20, 2022

(30) Foreign Application Priority Data
Dec. 7, 2021 (KR) 10-2021-0174083

(51) Int. Cl. H01L 27/32; H01L 51/56

(52) U.S. Cl. CPC H01L 27/3276; H01L 51/56; H01L 27/3213; H01L 2227/323

(57) ABSTRACT

A display device is provided, which may certainly become a dark spot in only an area in which particles occur. The display device comprises a substrate provided with a display area for displaying an image by a plurality of subpixels, a driving transistor provided over the substrate, first electrodes respectively provided in the plurality of subpixels over the driving transistor, a light emitting layer provided over the first electrodes, second electrodes respectively provided in the plurality of subpixels over the light emitting layer, and a cathode connection line provided between the plurality of subpixels. Each of the second electrodes includes a plurality of divided electrodes, and a bridge electrode connecting the plurality of divided electrodes to each other or connecting the plurality of divided electrodes with the cathode connection line.

### BACKGROUND

### Technical Field

The present disclosure relates to a display device.

### Description of the Related Art

A display device may include a first electrode, a light emitting layer, and a second electrode, which are sequentially deposited, and may emit light through the light emitting layer when a voltage is applied to the first electrode and the second electrode. In this display device, particles may occur on the first electrode during a manufacturing process, and in this case, a short may occur between the first electrode and the second electrode in the area in which the particles occur. For this reason, the display device has a problem in that all of subpixels in which particles occur become dark spots so as not to emit light. As a result, luminance of the display device may be deteriorated.

### BRIEF SUMMARY

The present disclosure has been made in view of the above problems and it is a technical benefit of the present disclosure to provide a display device that may minimize or reduce a size of a light emission area that becomes a dark spot.

It is another technical benefit of the present disclosure to provide a display device that may confine dark spots to only those areas in which particles occur.

In addition to the technical benefits of the present disclosure as mentioned above, additional technical benefits and features of the present disclosure will be clearly understood by those skilled in the art from the following description of the present disclosure.

In accordance with an aspect of the present disclosure, the above and other technical benefits can be accomplished by the provision of a display device comprising a substrate provided with a display area for displaying an image by a plurality of subpixels, a driving transistor provided over the substrate, first electrodes respectively provided in the plurality of subpixels over the driving transistor, a light emitting layer provided over the first electrodes, second electrodes respectively provided in the plurality of subpixels over the light emitting layer, and a cathode connection line provided between the plurality of subpixels. Each of the second electrodes includes a plurality of divided electrodes, and a bridge electrode connecting the plurality of divided electrodes to each other or connecting the plurality of divided electrodes with the cathode connection line.

In accordance with another aspect of the present disclosure, the above and other technical benefits can be accomplished by the provision of a display device comprising a substrate provided with transmissive areas and a plurality of subpixels disposed between the transmissive areas, first electrodes respectively provided in the plurality of subpixels over the substrate, a light emitting layer provided over the first electrode, second electrodes respectively provided in the plurality of subpixels over the light emitting layer, and a cathode connection line provided in the transmissive areas. Each of the second electrodes includes a plurality of divided electrodes, and a bridge electrode connecting the plurality of divided electrodes to each other or connecting the plurality of divided electrodes with the cathode connection line.

In accordance with another aspect of the present disclosure, the above and other technical benefits can be accomplished by the provision of a method, comprising: forming a second electrode layer on a light emitting layer over a substrate; forming a plurality of divided electrodes and a plurality of connecting portions by forming openings in the second electrode layer; and isolating one divided electrode from others of the plurality of divided electrodes by removing at least four connecting portions of the plurality of connecting portions.

### BRIEF DESCRIPTION OF THE SEVERAL VIEWS OF THE DRAWINGS

The above and other technical benefits, features and other advantages of the present disclosure will be more clearly understood from the following detailed description taken in conjunction with the accompanying drawings, in which:

FIG. 1 is a schematic plan view illustrating a display device according to one embodiment of the present disclosure;

FIG. 2 is a view illustrating an example of a pixel of a display panel shown in FIG. 1;

FIG. 3 is a cross-sectional view illustrating an example of line I-I′ of FIG. 2;

FIG. 4 is a cross-sectional view illustrating an example of line II-II′ of FIG. 2;

FIG. 5 is a cross-sectional view illustrating an example of line III-III′ of FIG. 2;

FIG. 6 is a view illustrating a second electrode provided in each of a plurality of subpixels;

FIG. 7 is a view illustrating an example that particles occur in one of a plurality of divided electrodes in FIG. 6;

FIG. 8 is a view illustrating another example of a pixel of a display panel shown in FIG. 1;

FIG. 9 is a cross-sectional view illustrating an example of line IV-IV′ of FIG. 8;

FIG. 10 is a view illustrating an example that particles occur in one of a plurality of divided electrodes in FIG. 8; and

FIG. 11 is a view illustrating a modified example of FIG. 8.

### DETAILED DESCRIPTION

Advantages and features of the present disclosure, and implementation methods thereof will be clarified through following embodiments described with reference to the accompanying drawings. The present disclosure may, however, be embodied in different forms and should not be construed as limited to the embodiments set forth herein. Rather, these embodiments are provided so that this disclosure will be thorough and complete, and will fully convey the scope of the present disclosure to those skilled in the art.

A shape, a size, a ratio, an angle, and a number disclosed in the drawings for describing embodiments of the present disclosure are merely an example, and thus, the present disclosure is not limited to the illustrated details. Like reference numerals refer to like elements throughout the specification. In the following description, when the detailed description of the relevant known function or configuration is determined to unnecessarily obscure the important point of the present disclosure, the detailed description will be omitted. In a case where ‘comprise,’ ‘have,’ and ‘include’ described in the present specification are used, another part may be added unless ‘only˜’ is used. The terms of a singular form may include plural forms unless referred to the contrary.

In construing an element, the element is construed as including an error range although there is no explicit description.

In describing a position relationship, for example, when the position relationship is described as ‘upon˜,’ ‘above˜,’ ‘below˜,’ and ‘next to˜,’ one or more portions may be arranged between two other portions unless ‘just’ or ‘direct’ is used.

It will be understood that, although the terms “first,” “second,” etc., may be used herein to describe various elements, these elements should not be limited by these terms. These terms are only used to distinguish one element from another. For example, a first element could be termed a second element, and, similarly, a second element could be termed a first element, without departing from the scope of the present disclosure.

In describing elements of the present disclosure, the terms “first,” “second,” etc., may be used. These terms are intended to identify the corresponding elements from the other elements, and basis, order, or number of the corresponding elements are not limited by these terms. The expression that an element is “connected” or “coupled” to another element should be understood that the element may directly be connected or coupled to another element but may directly be connected or coupled to another element unless specially mentioned, or a third element may be interposed between the corresponding elements.

Features of various embodiments of the present disclosure may be partially or overall coupled to or combined with each other, and may be variously inter-operated with each other and driven technically as those skilled in the art can sufficiently understand. The embodiments of the present disclosure may be carried out independently from each other, or may be carried out together in co-dependent relationship.

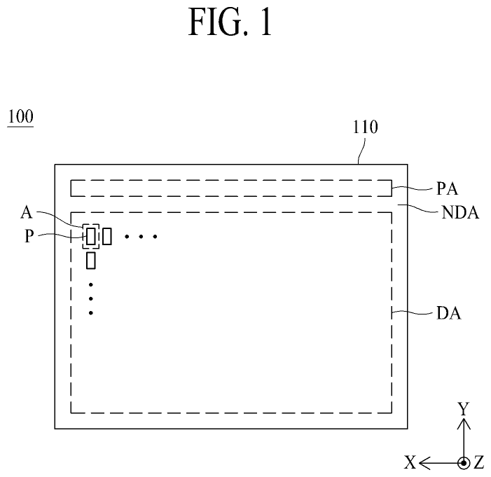

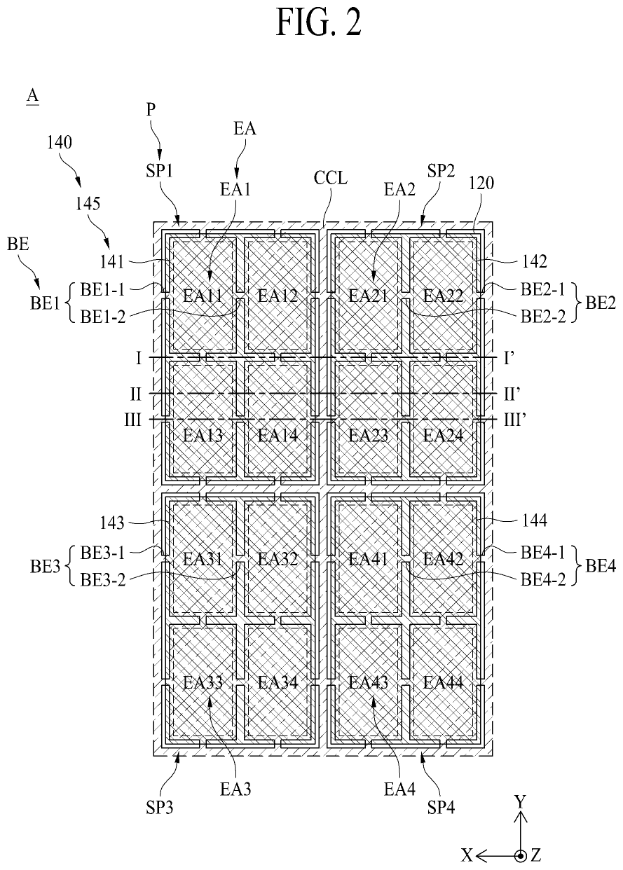

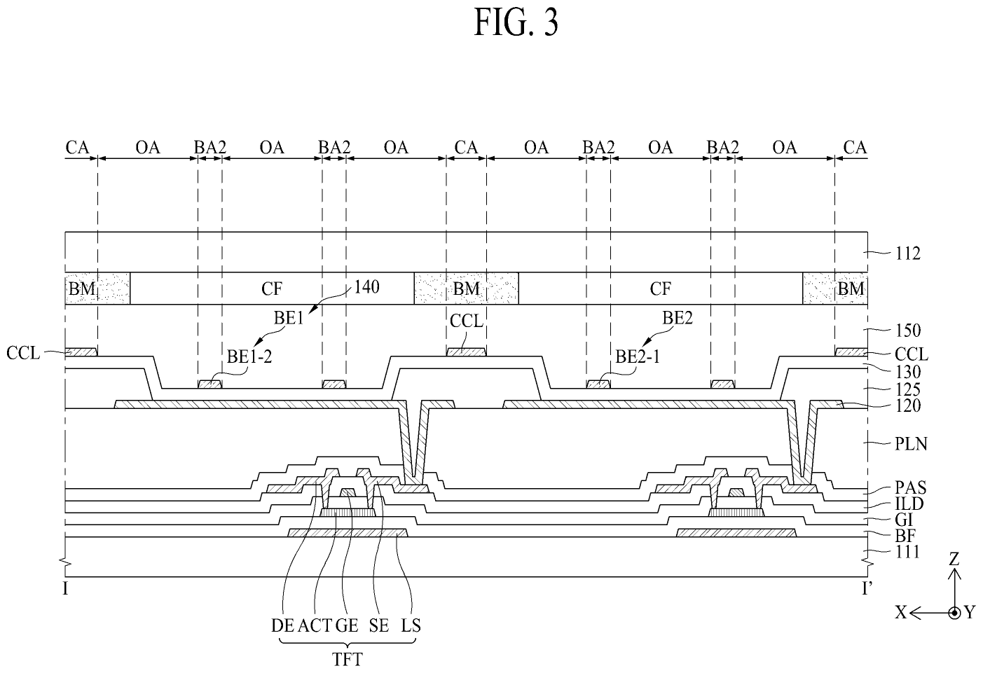

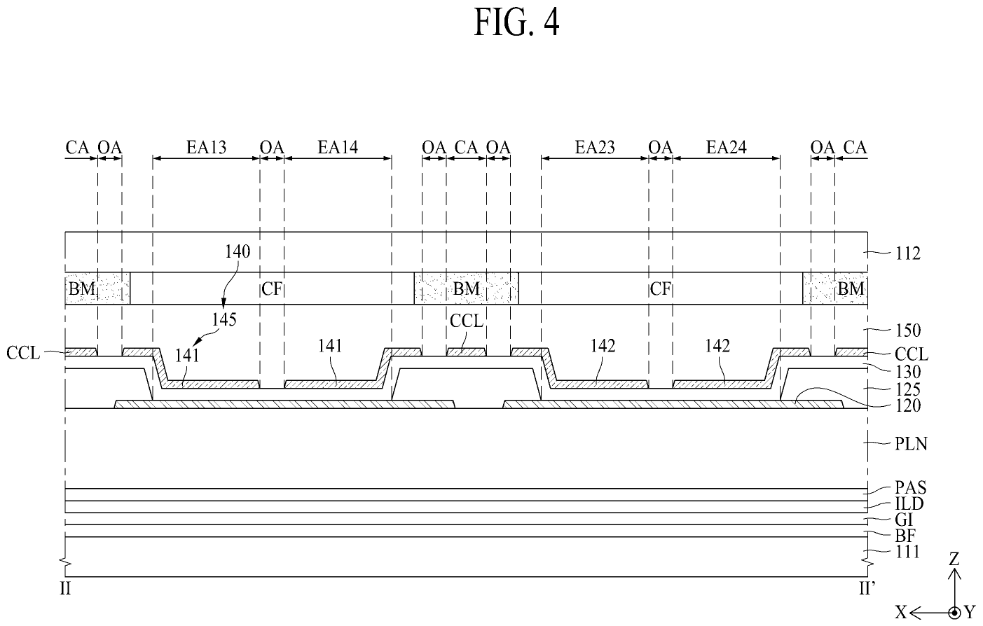

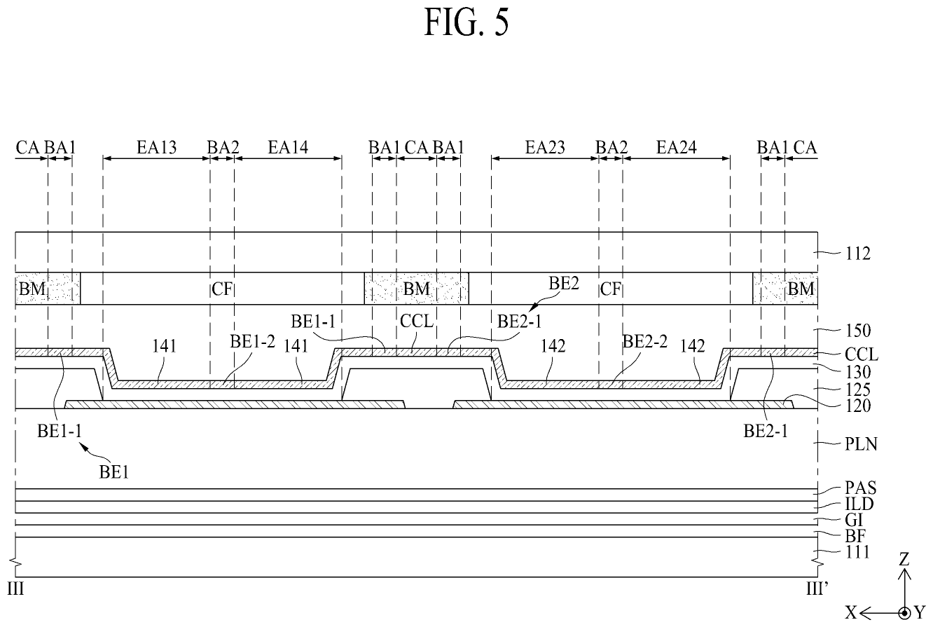

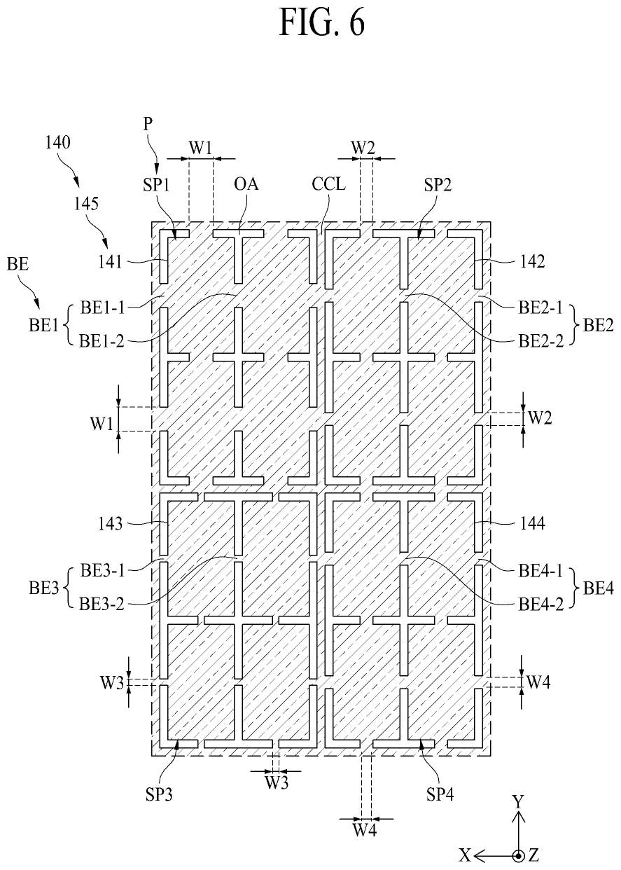

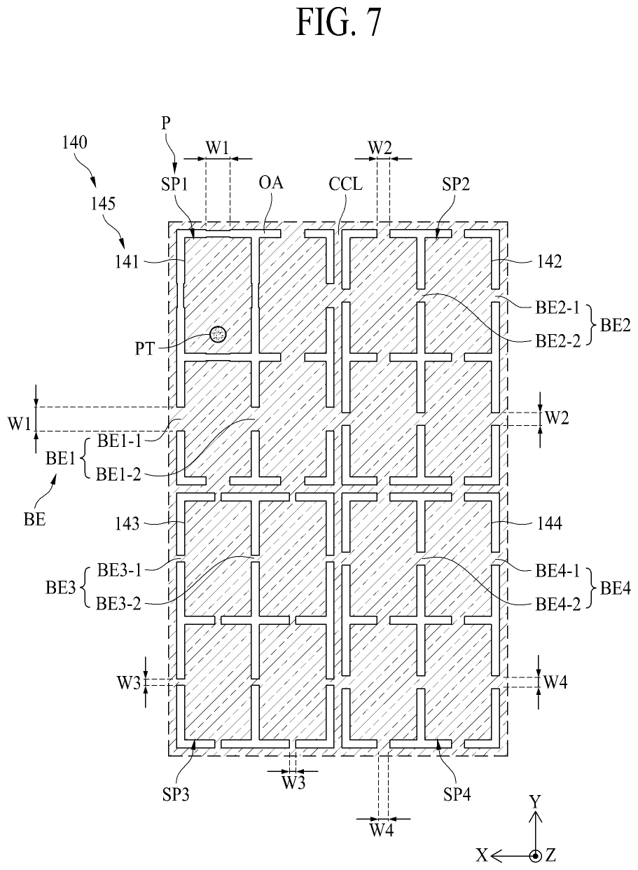

FIG. 1 is a schematic plan view illustrating a display device according to one embodiment of the present disclosure, FIG. 2 is a view illustrating an example of a pixel of a display panel shown in FIG. 1, FIG. 3 is a cross-sectional view illustrating an example of line I-I′ of FIG. 2, FIG. 4 is a cross-sectional view illustrating an example of line II-II′ of FIG. 2, FIG. 5 is a cross-sectional view illustrating an example of line III-III′ of FIG. 2, FIG. 6 is a view illustrating a second electrode provided in each of a plurality of subpixels, and FIG. 7 is a view illustrating an example that particles occur in one of a plurality of divided electrodes in FIG. 6.

Hereinafter, X axis indicates a line parallel with a scan line, Y axis indicates a line parallel with a data line, and Z axis indicates a height or thickness direction of a transparent display device 100.

Although a description has been described based on that the transparent display device 100 according to one embodiment of the present disclosure is embodied as an organic light emitting display device, the transparent display device 100 may be embodied as a liquid crystal display device, a plasma display panel (PDP), a Quantum dot Light Emitting Display (QLED) or an Electrophoresis display device.

Referring to FIGS. 1 to 7, a display device 100 according to one embodiment of the present disclosure includes a display panel 110. The display panel 110 includes a first substrate 111 and a second substrate 112, which face each other. The second substrate 112 may be an encapsulation substrate. The first substrate 111 may be a plastic film, a glass substrate, or a silicon wafer substrate formed using a semiconductor process. The second substrate 112 may be a plastic film, a glass substrate, or an encapsulation layer. The first substrate 111 and the second substrate 112 may be made of a transparent material.

The display panel 110 may include a display area DA in which pixels P are formed to display an image, and a non-display area NDA for not displaying an image. In some embodiments, the display area DA and the non-display area NDA do not overlap each other. The non-display area NDA may include a pad area PA in which pads such as power pads and data pads are disposed, and at least one scan driver (not shown).

The scan driver is connected to scan lines to supply scan signals. The scan driver may be disposed on one side or both sides of the display area DA in a gate driver in panel (GIP) mode. For example, the scan driver may be disposed on both sides of the display area DA, but is not limited thereto. The scan driver may be disposed only on one side of the display area DA.

The pixels P are disposed in the display area DA to emit a predetermined or selected light, thereby displaying an image. A light emission area EA may correspond to an area that emits light in the pixel P.

Each of the pixels P may include at least one of a first subpixel SP1, a second subpixel SP2, a third subpixel SP3, and a fourth subpixel SP4. The first subpixel SP1 includes a first light emission area EA1 emitting a first color light such as red light, the second subpixel SP2 includes a second light emission area EA2 emitting a second color light such as green light, the third subpixel SP3 includes a third light emission area EA3 emitting a third color light such as blue light, and the fourth subpixel SP4 may include a fourth light emission area EA4 emitting a fourth color light such as white light, but these subpixels are not limited thereto. Each of the pixels P may include subpixels that emit light with colors other than red, green, blue, and white. In addition, various modifications may be made in the arrangement order of the subpixels SP1, SP2, SP3 and SP4.

The light emission areas EA1, EA2, EA3 and EA4 respectively provided in the plurality of subpixels SP1, SP2, SP3 and SP4 may include a plurality of divided light emission areas. In detail, the first light emission area EA1 provided in the first subpixel SP1 is divided into four and thus may include a first divided light emission area EA11, a second divided light emission area EA12, a third divided light emission area EA13 and a fourth divided light emission area EA14. The second light emission area EA2 provided in the second subpixel SP2 is divided into four and thus may include a first divided light emission area EA21, a second divided light emission area EA22, a third divided light emission area EA23 and a fourth divided light emission area EA24. The third light emission area EA3 provided in the third subpixel SP3 is divided into four and thus may include a first divided light emission area EA31, a second divided light emission area EA32, a third divided light emission area EA33 and a fourth divided light emission area EA34. The fourth light emission area EA4 provided in the fourth subpixel SP4 is divided into four and thus may include a first divided light emission area EA41, a second divided light emission area EA42, a third divided light emission area EA43 and a fourth divided light emission area EA44. It should be understood that “divided” or “divided into” includes the meaning that one group or element contains different items or objects. The term “divided into” does not require the action of dividing. The term divided means it is possible, by the removal of one or more bridges to electrically isolate the electrode from all other electrodes, namely, fully electrically and physically isolate (e.g., divide) one electrode from other electrodes. Thus, the term “divided electrode” includes within it the meaning that this electrode can be electrically isolated from all other electrodes, namely, it has been divided by removal of the bridge electrodes connecting it to other electrodes.

Hereinafter, for convenience of description, the first subpixel SP1 is a red subpixel emitting red light, the second subpixel SP2 is a green subpixel emitting green light, the third subpixel SP3 is a blue subpixel emitting blue light, and the fourth subpixel SP4 is a white subpixel emitting white light.

Each of the plurality of subpixels SP1, SP2, SP3 and SP4 may include a circuit element, which includes at least one transistor and a capacitor, and a light emitting element. The at least one transistor may include a driving transistor TFT, a switching transistor, and a sensing transistor.

The switching transistor may be switched in accordance with a scan signal supplied to a scan line to charge a data voltage, which is supplied from the data line, to the driving transistor TFT.

The sensing transistor may serve to sense a threshold voltage deviation of the driving transistor TFT, which causes deterioration of image quality, in accordance with a sensing signal.

The driving transistor TFT may be switched in accordance with the data voltage supplied to the switching transistor to generate a data current from a power source supplied from the pixel power line, thereby supplying the data current to the first electrode 120 of the subpixels SP1, SP2, SP3 and SP4. The driving transistor TFT may include an active layer ACT, a gate electrode GE, a source electrode SE and a drain electrode DE.

The capacitor may serve to maintain the data voltage supplied to the driving transistor TFT for one frame. The capacitor may include two capacitor electrodes, but is not limited to. In one embodiment, the capacitor may include three electrodes.

In detail, the active layer ACT may be provided over a first substrate 111. The active layer ACT may be formed of a silicon-based semiconductor material or an oxide-based semiconductor material.

As shown in FIG. 3, a light shielding layer LS may be provided between the first substrate 111 and the active layer ACT. The light shielding layer LS serves to shield external light incident over the active layer ACT in the area where the driving transistor TFT is formed. The light shielding layer LS may be formed of a single layer or multiple layers made of any one of molybdenum (Mo), aluminum (Al), chromium (Cr), gold (Au), titanium (Ti), nickel (Ni), neodymium (Nd) and copper (Cu) or their alloy. A buffer layer BF may be provided between the light shielding layer LS and the active layer ACT.

A gate insulating layer GI may be provided over the active layer ACT. The gate insulating layer GI may be formed of an inorganic layer, for example, a silicon oxide layer (SiOx), a silicon nitride layer (SiNx), or multiple layers of SiOx and SiNx.

A gate electrode GE may be provided over the gate insulating layer GI. The gate electrode GE may be formed of a single layer or multiple layers made of one of molybdenum (Mo), aluminum (Al), chromium (Cr), gold (Au), titanium (Ti), nickel (Ni), neodymium (Nd) and copper (Cu), or their alloy.

An interlayer dielectric layer ILD may be provided over the gate electrode GE. The interlayer dielectric layer ILD may be formed of an inorganic layer, for example, a silicon oxide layer (SiOx), a silicon nitride layer (SiNx), or multiple layers of SiOx and SiNx.

The source electrode SE and the drain electrode DE may be provided over the interlayer dielectric layer ILD. One of the source electrode SE and the drain electrode DE may be connected to the active layer ACT through a contact hole that passes through the gate insulating layer GI and the interlayer dielectric layer ILD.

The source electrode SE and the drain electrode DE may be formed of a single layer or multiple layers made of one of molybdenum (Mo), aluminum (Al), chromium (Cr), gold (Au), titanium (Ti), nickel (Ni), neodymium (Nd) and copper (Cu), or their alloy.

A passivation layer PAS for protecting the driving transistor TFT may be provided over the source electrode SE and the drain electrode DE. A planarization layer PLN for planarizing a step difference due to the driving transistor TFT may be provided over the passivation layer PAS. The planarization layer PLN may be formed of an organic layer such as an acrylic resin, an epoxy resin, a phenolic resin, a polyamide resin and a polyimide resin.

A light emitting element, which includes a first electrode 120, an organic light emitting layer 130 and a second electrode 140, and a bank 125 may be provided over the planarization layer PLN.

The first electrode 120 may be provided over the planarization layer PLN for each of the subpixels SP1, SP2, SP3 and SP4. One first electrode 120 is provided in the first subpixel SP1, the other first electrode 120 is provided in the second subpixel SP2, another first electrode 120 is provided in the third subpixel SP3, and another first electrode 120 is provided in the fourth subpixel SP4.

At this time, the first electrode 120 may be provided in each of the plurality of subpixels SP1, SP2, SP3 and SP4 in one pattern. That is, the first electrode 120 may be provided in one pattern without being divided as much as the number of divided light emission areas of the corresponding subpixel. The first electrode 120 provided in one pattern may be electrically connected to a source electrode SE or a drain electrode DE of a driving transistor TFT through a contact hole passing through a passivation layer PAS and a planarization layer PLN.

The first electrode 120 may be formed of a metal material having high reflectance, such as a stacked structure (Ti/Al/Ti) of aluminum and titanium, a stacked structure (ITO/Al/ITO) of aluminum and ITO, an Ag alloy, a stacked structure (ITO/Ag alloy/ITO) of Ag alloy and ITO, a MoTi alloy, and a stacked structure (ITO/MoTi alloy/ITO) of MoTi alloy and ITO. The Ag alloy may be an alloy of silver (Ag), palladium (Pd), copper (Cu), etc. The MoTi alloy may be an alloy of molybdenum (Mo) and titanium (Ti). The first electrode 120 may be an anode electrode.

The bank 125 may be provided over the planarization layer PLN. The bank 125 may be provided between the first electrodes 120 provided in each of the first to fourth subpixels SP1, SP2, SP3, and SP4. The bank 125 may be provided to at least partially cover an edge of each of the first electrodes 120 and expose a portion of each of the first electrodes 120. Therefore, the bank 125 may prevent a problem in which light emitting efficiency is deteriorated due to concentration of a current on an end of each of the first electrodes 120.

The bank 125 may define (e.g., laterally surround) light emission areas EA1, EA2, EA3 and EA4 of the subpixels SP1, SP2, SP3 and SP4. The light emission areas EA1, EA2, EA3 and EA4 of each of the subpixels SP1, SP2, SP3 and SP4 represent an area in which the first electrode 120, the organic light emitting layer 130 and the second electrode 140 are sequentially stacked and holes from the first electrode 120 and electrons from the second electrode 140 are combined with each other in the organic light emitting layer 130 to emit light. In this case, the area in which the bank 125 is provided may become the non-light emission area NTA because light is not emitted therefrom, and the area in which the bank 125 is not provided and the first electrode is exposed may become the light emission areas EA1, EA2, EA3 and EA4.

The bank 125 may be formed of an organic layer such as an acrylic resin, an epoxy resin, a phenolic resin, a polyamide resin, and a polyimide resin.

The organic light emitting layer 130 may be disposed over the first electrode 120. The organic light emitting layer 130 may include a hole transporting layer, a light emitting layer and an electron transporting layer. In this case, when a voltage is applied to the first electrode 120 and the second electrode 140, holes and electrons move to the light emitting layer through the hole transporting layer and the electron transporting layer, respectively and are combined with each other in the light emitting layer to emit light.

In one embodiment, the organic light emitting layer 130 may be a common layer commonly provided in the subpixels SP1, SP2, SP3 and SP4. In this case, the light emitting layer may be a white light emitting layer for emitting white light.

In another embodiment, the light emitting layer of the organic light emitting layer 130 may be provided for each of the subpixels SP1, SP2, SP3 and SP4. For example, a red light emitting layer for emitting red light may be provided in the first subpixel SP1, a green light emitting layer for emitting green light may be provided in the second subpixel SP2, a blue light emitting layer for emitting blue light may be provided in the third subpixel SP3, and a white light emitting layer for emitting white light may be provided in the fourth subpixel SP4.

The second electrode 140 may be provided over an organic light emitting layer 130 and a bank 125. The second electrode 140 may be provided in each of the plurality of subpixels SP1, SP2, SP3 and SP4. The second electrodes 140 respectively provided in the plurality of subpixels SP1, SP2, SP3 and SP4 may be connected to each other through a cathode connection line CCL.

The cathode connection line CCL is to connect the second electrodes 140 respectively provided to be patterned in the plurality of subpixels SP1, SP2, SP3 and SP4 with each other, and may be provided between the plurality of subpixels SP1, SP2, SP3 and SP4. The cathode connection line CCL may be extended in a first direction (X-axis direction) or a second direction (Y-axis direction) between the plurality of subpixels SP1, SP2, SP3 and SP4. Alternatively, the cathode connection line CCL may have a lattice shape extended in the first direction (X-axis direction) and the second direction (Y-axis direction) between the plurality of subpixels SP1, SP2, SP3 and SP4 as shown in FIG. 2. The cathode connection line CCL may be provided in the same layer as the second electrode 140 and integrally provided with the second electrode 140 as shown in FIGS. 3 to 5. That is, a portion of one layer may be a cathode connection area CA in which the cathode connection line CCL is disposed. In another embodiment, the cathode connection line CCL may be provided in a different layer from the second electrode 140, and in this case, the cathode connection line CCL may be electrically connected to the second electrode 140 through a contact hole.

The second electrode 140 provided in each of the plurality of subpixels SP1, SP2, SP3 and SP4 may be comprised of a plurality of divided electrodes 145 and a bridge electrode BE.

Two or more divided electrodes 145 may be provided, and may be spaced apart from each other in the first direction (X-axis direction) or the second direction (Y-axis direction).

In one embodiment, the plurality of divided electrodes 145 may be provided as many as the number of divided light emission areas. For example, as shown in FIG. 2, four divided electrodes 145 may be provided to be equal to the number of divided light emission areas. In this case, the plurality of divided electrodes 145 may be disposed to respectively correspond to the plurality of divided light emission areas. For example, four divided electrodes 141 provided in the first subpixel SP1 may be disposed to respectively correspond to four first divided light emission areas EA11, EA12, EA13 and EA14.

As described above, the four divided electrodes 145 are provided to be equal to the number of divided light emission areas, but the present disclosure is not limited thereto. Two divided electrodes 145 may be provided, or five or more divided electrodes 145 may be provided. Hereinafter, for convenience of description, the following description will be based on that the four divided electrodes 145 are provided.

The bridge electrode BE may connect the plurality of divided electrodes 145 to each other or connect the plurality of divided electrodes 145 with the cathode connection line CCL.

In detail, the second electrode 140 provided in the first subpixel SP1 may include a plurality of first divided electrodes 141 and a first bridge electrode BE1.

The plurality of first divided electrodes 141 may be disposed to respectively correspond to the plurality of first divided light emission areas EA11, EA12, EA13 and EA14. That is, the plurality of first divided electrodes 141 may at least partially overlap the plurality of first divided light emission areas EA11, EA12, EA13 and EA14, respectively.

In addition, the plurality of first divided electrodes 141 may be spaced apart from each other by an opening area OA formed to expose the organic light emitting layer 130 between the plurality of first divided light emission areas EA11, EA12, EA13 and EA14, that is, the opening area OA may be between the plurality of first divided electrodes 141. Also, the plurality of first divided electrodes 141 may be spaced apart from the cathode connection line CCL.

The first bridge electrode BE1 may include at least one of a first connection portion BE1-1 and a second connection portion BE1-2.

The first connection portion BE1-1 of the first bridge electrode BE1 may be disposed between the plurality of first divided electrodes 141 and the cathode connection line CCL to connect the plurality of first divided electrodes 141 with the cathode connection line CCL. The first connection portion BE1-1 may be provided in a plural number. Each of the plurality of first connection portions BE1-1 may be disposed between one of the plurality of first divided electrodes 141 and the cathode connection line CCL, such that one end thereof may be connected to one of the plurality of first divided electrodes 141 and the other end thereof may be connected to the cathode connection line CCL.

Therefore, each of the plurality of first divided electrodes 141 may be connected to one or more first connection portions BE1-1, and may be connected to the cathode connection line CCL through one or more first connection portions BE1-1. For example, as shown in FIG. 2, the first divided electrode 141 disposed in the first divided light emission area EA11 may be connected to two first connection portions BE1-1, and may be connected to the cathode connection line CCL through two first connection portions BE1-1.

As described above, the plurality of first connection portions BE1-1 are disposed between the first subpixel SP1 and the other subpixels adjacent to the first subpixel SP1, and thus may at least partially overlap the bank 125.

The second connection portion BE1-2 of the first bridge electrode BE1 may be disposed between the plurality of first divided electrodes 141 to connect the plurality of first divided electrodes 141 to each other. The second connection portion BE1-2 may be provided in a plural number. Each of the plurality of second connection portions BE1-2 may be disposed between two first divided electrodes 141 adjacent to each other, such that one end thereof may be connected to one of the first divided electrodes 141, and the other end thereof may be connected to the other first divided electrode 141.

Therefore, each of the plurality of first divided electrodes 141 may be connected to one or more second connection portions BE1-2, and may be connected to another first divided electrode 141 disposed to be adjacent thereto through one or more second connection portions BE1-2. For example, as shown in FIG. 2, the first divided electrode 141 disposed in the first divided light emission area EA11 may be connected to the two second connection portions BE1-2. The first divided electrode 141 disposed in the first divided light emission area EA11 may be connected to the first divided electrode 141 disposed in the second divided light emission area EA12 and the first divided electrode 141 disposed in the third divided light emission area EA13 through the two second connection portions BE1-2.

As described above, the plurality of second connection portions BE1-2 are disposed between the plurality of first divided light emission areas EA11, EA12, EA13 and EA14, and thus may not overlap the bank 125.

The first and second connection portions BE1-1 and BE2-2 may be formed in the same layer as the first divided electrodes 141, and may be integrally formed with the first divided electrodes 141. That is, the second electrode 140 provided in the first subpixel SP1 may be divided into a first bridge area BA1 in which the first connection portion BE1-1 is disposed, a second bridge area BA2 in which the second connection portion BE1-2 is disposed, and the first light emission area EA1 in which the first divided electrode 141 is disposed to emit light.

The second electrode 140 provided in the second subpixel SP2 may include a plurality of second divided electrodes 142 and a second bridge electrode BE2, and the second bridge electrode BE2 may include at least one of a first connection portion BE2-1 and a second connection portion BE2-2.

The second electrode 140 provided in the third subpixel SP3 may include a plurality of third divided electrodes 143 and a third bridge electrode BE3, and the third bridge electrode BE3 may include at least one of a first connection portion BE3-1 and a second connection portion BE3-2.

The second electrode 140 provided in the fourth subpixel SP4 may include a plurality of fourth divided electrodes 144 and a fourth bridge electrode BE4, and the fourth bridge electrode BE4 may include at least one of a first connection portion BE4-1 and a second connection portion BE4-2.

The second electrode 140 provided in the second subpixel SP2, the third subpixel SP3 and the fourth subpixel SP4 has a position different from that of the second electrode 140 provided in the first subpixel SP1 but has the substantially same configuration as that of the second electrode 140 provided in the first subpixel SP1. Therefore, the description of the second electrode 140 provided in the first subpixel SP1 may be equally applied to the second electrode 140 provided in the second subpixel SP2, the third subpixel SP3 and the fourth subpixel SP4.

Hereinafter, differences between the second electrodes 140 respectively provided in the first subpixel SP1, the second subpixel SP2, the third subpixel SP3 and the fourth subpixel SP4 will be described, and repeated descriptions will be omitted.

The bridge electrode BE of the second electrode 140 may be provided to have different widths for the respective subpixels SP1, SP2, SP3 and SP4. In this case, the width may represent a length of a side of the bridge electrode BE that is in contact with the divided electrode 145.

In detail, in the display panel 110 according to one embodiment of the present disclosure, the width of the bridge electrode BE of the second electrode 140 may be formed differently depending on a limit current of a driving transistor TFT of each of the subpixels SP1, SP2, SP3 and SP4.

A current selected for each of the first to fourth subpixels SP1, SP2, SP3 and SP4 may be different depending on a color of light emitted from each of the subpixels. A size of the driving transistor TFT provided in each of the first to fourth subpixels SP1, SP2, SP3 and SP4 may be determined in consideration of the selected current. For example, the current selected for the first subpixel SP1, which emits red light, among the first to fourth subpixels SP1, SP2, SP3 and SP4 may be the largest. In this case, the driving transistor TFT connected to the first electrode 120 of the first subpixel SP1 may have a size greater than that of the driving transistor TFT of each of the second to fourth subpixels SP2, SP3 and SP4 to have a high limit current. As another example, the current selected for the third subpixel SP3, which emits blue light, among the first to fourth subpixels SP1, SP2, SP3 and SP4 may be the smallest. In this case, the driving transistor TFT connected to the first electrode 120 of the third subpixel SP3 may have a size smaller than that of the driving transistor TFT of each of the first, second and fourth subpixels SP1, SP2 and SP4 to have a low limit current.

A magnitude of a current flowing in the bridge electrode BE of the second electrode 140 provided in each of the first to fourth subpixels SP1, SP2, SP3 and SP4 may vary depending on the sizes of the driving transistors TFT. When the size of the driving transistor TFT is large, the current supplied from the driving transistor TFT is large, so that the current flowing through the second electrode 140 may be large. On the other hand, when the size of the driving transistor TFT is small, the current supplied from the driving transistor TFT is small, so that the current flowing through the second electrode 140 may be small.

In the display panel 110 according to one embodiment of the present disclosure, the width of the bridge electrode BE of the second electrode 140 may be adjusted to adjust resistance of the bridge electrode BE. Therefore, the display panel 110 according to one embodiment of the present disclosure may ensure that the bridge electrode BE connected to the divided electrode 145 in which particles occur may be melted in each of the first to fourth subpixels SP1, SP2, SP3 and SP4 to separate the divided electrode 145 in which particles occur.

For example, the driving transistor TFT connected to the first electrode 120 of the first subpixel SP1 may be the largest, the driving transistor TFT connected to the first electrode 120 of the second subpixel SP2 may be the second largest, the driving transistor TFT connected to the first electrode 120 of the fourth subpixel SP4 may be the third largest, and the driving transistor TFT connected to the first electrode 120 of the third subpixel SP3 may be the smallest. For example, the driving transistor TFT connected to the first electrode 120 of the red subpixel SP1 may be the largest, the driving transistor TFT connected to the first electrode 120 of the green subpixel SP2 may be the second largest, the driving transistor TFT connected to the first electrode 120 of the white subpixel SP4 may be the third largest, and the driving transistor TFT connected to the first electrode 120 of the blue subpixel SP3 may be the smallest.

In this case, a third width W3 of the third bridge electrode BE3 of the second electrode 140 provided in the third subpixel SP3 may be formed to be smaller than a fourth width W4 of the fourth bridge electrode BE4 of the second electrode 140 provided in the fourth subpixel SP4 as shown in FIG. 6. Therefore, the display panel 110 according to one embodiment of the present disclosure may increase resistance of the third bridge electrode BE3 of the third subpixel SP3 even though the driving transistor TFT provided in the third subpixel SP3 has a low limit current. In addition, the display panel 110 according to one embodiment of the present disclosure may generate heat sufficient to melt the third bridge electrode BE3 when a short line occurs between the first electrode 120 and the third divided electrode 143.

In addition, the fourth width W4 of the fourth bridge electrode BE4 of the second electrode 140 provided in the fourth subpixel SP4 may be formed to be smaller than a second width W2 of the second bridge electrode BE2 of the second electrode 140 provided in the second subpixel SP2. The current flowing through the second electrode 140 provided in the fourth subpixel SP4 may be smaller than that flowing through the second electrode 140 provided in the second subpixel SP2. In the display panel 110 according to one embodiment of the present disclosure, the fourth width W4 of the fourth bridge electrode BE4 of the fourth subpixel SP4 is formed to be smaller than the second width W2 of the second bridge electrode BE2 of the second subpixel SP2, whereby resistance of the fourth bridge electrode BE4 of the fourth subpixel SP4 may be increased. In addition, the display panel 110 according to one embodiment of the present disclosure may generate heat sufficient to melt the fourth bridge electrode BE4 when a short line occurs between the first electrode 120 and the fourth divided electrode 144.

In addition, the second width W2 of the second bridge electrode BE2 of the second electrode 140 provided in the second subpixel SP2 may be formed to be smaller than the first width W1 of the first bridge electrode BE1 of the second electrode 140 provided in the first subpixel SP1. The current flowing through the second electrode 140 of the second subpixel SP2 may be smaller than that flowing through the second electrode 140 of the first subpixel SP1. In the display panel 110 according to one embodiment of the present disclosure, the second width W2 of the second bridge electrode BE2 of the second subpixel SP2 may be formed to be smaller than the first width W1 of the first bridge electrode BE1 of the first subpixel SP1, whereby resistance of the second bridge electrode BE2 of the second subpixel SP2 may be increased. In addition, the display panel 110 according to one embodiment of the present disclosure may generate heat sufficient to melt the second bridge electrode BE2 when a short line occurs between the first electrode 120 and the second divided electrode 142.

As a result, in the display panel 110 according to one embodiment of the present disclosure, the third width W3 of the third bridge electrode BE3 of the third subpixel SP3 may be the smallest, the fourth width W4 of the fourth bridge electrode BE4 of the fourth subpixel SP4 may be the second smallest, the second width W2 of the second bridge electrode BE2 of the second subpixel SP2 may be the third smallest, and the first width W1 of the first bridge electrode of the first subpixel SP1 may be the largest.

For example, in the display panel 110 according to one embodiment of the present disclosure, the width W3 of the bridge electrode BE3 in the blue subpixel SP3 may be the smallest, the width W4 of the bridge electrode BE4 in the white subpixel SP4 may be the second smallest, the width W2 of the bridge electrode BE2 in the green subpixel SP2 may be the third smallest, and the width W1 of the bridge electrode BE1 in the red subpixel SP1 may be the largest.

In the display panel 110 according to one embodiment of the present disclosure, when the current applied from the driving transistor TFT is small, the width of the bridge electrode BE connected to the corresponding driving transistor TFT may be reduced, whereby resistance of the bridge electrode BE may be increased. Therefore, the display panel 110 according to one embodiment of the present disclosure may ensure that the bridge electrode BE, which is in contact with the divided electrode 145 in which particles occur, may be melted when the particles occur, to electrically separate the divided electrode 145 in which particles occur, from the other elements.

In FIG. 5, the bridge electrode BE of the second electrode 140 is formed differently depending on the limit current of the driving transistor TFT of each of the subpixels SP1, SP2, SP3 and SP4, but is not limited thereto. In another embodiment, the number of bridge electrodes BE of the second electrode 140 may be formed differently depending on the limit current of the driving transistor TFT of each of the subpixels SP1, SP2, SP3 and SP4. For example, the first subpixel SP1 having a large limit current of the driving transistor TFT may include more bridge electrodes BE than the other subpixels SP2, SP3 and SP4.

On the other hand, the third subpixel SP3 having a small limit current of the driving transistor TFT may have a smaller number of the bridge electrodes BE than the other subpixels SP1, SP2 and SP4. That is, the display panel 110 according to another embodiment of the present disclosure may increase resistance of the bridge electrode BE by reducing the number of bridge electrodes BE connected to the driving transistor TFT when the current applied from the driving transistor TFT is small. Therefore, the display panel 110 according to another embodiment of the present disclosure may ensure that the bridge electrodes BE, which are in contact with the divided electrode 145 in which particles occur, may be melted when the particles occur, to electrically separate the divided electrode 145 in which particles occur, from the other elements.

The second electrodes 140 respectively provided in the plurality of subpixels SP1, SP2, SP3 and SP4 may be common layers that are electrically connected to each other to apply the same voltage. The second electrodes 140 may be made of a conductive material capable of transmitting light. For example, the second electrodes 140 may be formed of a low resistance metal material such as silver (Ag) or an alloy of magnesium (Mg) and silver (Ag).

In the display panel 110 according to one embodiment of the present disclosure, the second electrode 140 provided in each of the plurality of subpixels SP1, SP2, SP3 and SP4 includes a plurality of divided electrodes 145 and a bridge electrode BE. Therefore, in the display panel 110 according to one embodiment of the present disclosure, even though particles occur in any one of the plurality of divided electrodes 145, only an area where the corresponding divided electrode is provided may become a dark spot certainly and the other divided electrodes may be normally operated.

In detail, as shown in FIG. 6, in the display panel 110 according to one embodiment of the present disclosure, particles P may occur in any one of the plurality of divided electrodes 145. In this case, in the display panel 110 according to one embodiment of the present disclosure, a short may occur between the first electrode 120 and the divided electrode 145 of the second electrode 140 in the area in which the particles are positioned. When an aging signal is applied to the light emitting element during an aging process, a current may be concentrated on the area where the first electrode 120 and the divided electrode 145 of the second electrode 140 are short-circuited. In this case, the aging process may be performed to prevent quality or reliability from being deteriorated before the product is released. The aging signal may correspond to a power source or signal applied to the light emitting element such that a predetermined or selected current flows in the light emitting element, and may be, for example, a reverse bias voltage.

In the display panel 110 according to one embodiment of the present disclosure, as the current is concentrated on the divided electrode 145 in which particles occur, a large amount of current may flow in the bridge electrode BE that is in contact with the divided electrode 145 in which particles occur. In particular, since the bridge electrode BE is a connection electrode having a width and an area, which are remarkably smaller than those of the divided electrode 145, the bridge electrode BE may have high resistance. Therefore, significant heat may be generated in the bridge electrode BE by Joule heating. As the current is concentrated on the divided electrode 145 in which particles occur, the bridge electrode BE, which is in contact with the divided electrode 145 in which particles occur, may be melted to electrically separate the divided electrode 145 in which particles occur, from the other divided electrodes 145 as shown in FIG. 6.

The display panel 110 according to one embodiment of the present disclosure may disconnect the connection between the divided electrodes 145 in which particles occur and the other divided electrodes 145, thereby emitting light in the area where the divided electrode 145, in which particles do not occur, is provided.

One of methods of allowing the area in which particles occur to become a dark spot is to form the first electrode 120 by the plurality of divided electrodes. Since the first electrode 120 is generally formed of a plurality of layers and is made of a reflective metal material having a high melting point such as Ti, Al, Ag, etc., the first electrode 120 may not be melted even though a high resistance area is formed. For this reason, when particles occur in one of the plurality of divided electrodes constituting the first electrode 120, a connection line connecting the divided electrode, in which particles occur, with the driving transistor TFT may be cut by a laser, so that the divided electrode in which particles occur and the driving transistor TFT may be disconnected from each other.

However, in this method, other lines and peripheral elements may be damaged due to the laser, and it is beneficial that other lines and circuit elements should be designed not to overlap a laser cutting area and thus prevented from being damaged by the laser. In this case, since the lines and the circuit elements should be designed in a limited space, the size of the light emission area EA may be reduced to make sure of the laser cutting area. In addition, since a laser cutting process for searching for a divided electrode in which particles occur and disconnecting the divided electrode in which particles occur from the driving transistor TFT should be added, the process becomes complicated and the process time may be increased.

In the display panel 110 according to one embodiment of the present disclosure, the second electrode 140, which has a relatively low melting point, not the first electrode 120 is formed of the plurality of divided electrodes 145, and the plurality of divided electrodes 145 are connected to each other by the bridge electrode BE having high resistance.

When particles occur in any one of the plurality of divided electrodes 145, as the current is concentrated on the divided electrode 145 in which particles occur, a large amount of current flows in the bridge electrode BE that is in contact with the divided electrode 145 in which particles occur. For example, when particles occur in the first divided electrode 141 disposed in the first divided light emission area EA11 of the first subpixel SP1, as the current is concentrated on the first divided electrode 141 in which particles occur, a large amount of current may flow in the first bridge electrode BE1 that is in contact with the first divided electrode 141 in which particles occur. Therefore, the first bridge electrode BE1 that is in contact with the first division electrode 141 in which particles occur may generate significant heat and be melted by Joule heating.

As a result, in the display panel 110 according to one embodiment of the present disclosure, the divided electrode 141 in which particles occur may be electrically separated from the first divided electrodes 141, which are disposed in the second to fourth divided light emission areas EA12, EA13 and EA14 of the first subpixel SP1, without laser cutting.

Therefore, in the display panel 110 according to one embodiment of the present disclosure, the other lines and circuit elements may be prevented from being damaged by the laser, and since a separate laser cutting process may be omitted, the process may be simplified and the process time may be shortened.

Also, the display panel 110 according to one embodiment of the present disclosure may minimize or reduce size reduction of the light emission area EA in forming the second electrode 140 to be patterned.

In addition, in the display panel 110 according to one embodiment of the present disclosure, when particles occur, the light emitting layer 130 and the divided electrode 145 of the second electrode 140 in the area in which particles occur may be melted or sublimated by Joule heating, so that aging may be primarily performed. In the display panel 110 according to one embodiment of the present disclosure, only the area in which particles occur may locally become a dark spot by primary aging. However, the primary aging may be performed when sufficient heat is not generated in the area in which particles are positioned, or when the divided electrode and the second electrode 140 are electrically connected to each other without being insulated from each other depending on a state that the light emitting layer 130 and the divided electrode 145 of the second electrode 140 are melted.

In this case, in the display panel 110 according to one embodiment of the present disclosure, as the current is still concentrated on the divided electrode 145 in which particles occur, the bridge electrode BE may be melted by Joule heating, whereby aging may secondarily be performed. Therefore, in the display panel 110 according to one embodiment of the present disclosure, only a portion, in which particles occur, among the subpixels may become a dark spot, whereby the entire subpixels may be prevented from becoming dark spots. It should be understood that, while the preceding description is in terms of isolating a single divided electrode (e.g., the divided electrode 141 shown in FIG. 7) from other divided electrodes of the same subpixel (e.g., the first subpixel SP1), other divided electrodes of other subpixels (e.g., the subpixels SP2, SP3, SP4), or both, by melting four of the first and second connecting portions BE1-1, BE1-2, the embodiments are not limited to isolating the single divided electrode. In some embodiments, two neighboring divided electrodes (e.g., horizontally-neighboring or vertically-neighboring divided electrodes 141 of the first subpixel SP1) may be isolated from others of the divided electrodes by melting at least six of the first and second connecting portions BE1-1, BE1-2, such as the six first connecting portions BE1-1, or such as four of the first connecting portions BE1-1 and two of the second connecting portions BE1-2. In some embodiments, four neighboring divided electrodes (e.g., the four divided electrodes 141 of the first subpixel SP1) may be isolated from others of the divided electrodes by melting at least eight of the first and second connecting portions BE1-1, BE1-2, such as eight of the first connection portions BE1-1. In many cases, when the first connection portions BE1-1 associated with the divided electrodes to be isolated are melted, the second connection portions BE1-2 associated with the divided electrodes to be isolated are melted simultaneously, for example, in the presence of the aging signal (e.g., the reverse bias voltage).

An encapsulation layer 150 may be provided over the light emitting elements. The encapsulation layer 150 may be provided over the second electrode 140 and the cathode connection line CCL to at least partially cover the second electrode 140 and the cathode connection line CCL. The encapsulation layer 150 serves to prevent oxygen or water from being permeated into the organic light emitting layer 130 and the second electrode 140. To this end, the encapsulation layer 150 may include at least one inorganic layer and at least one organic layer.

Meanwhile, although not shown in FIG. 3, FIG. 4 and FIG. 5, a capping layer may additionally be provided between the second electrode 140 and the encapsulation layer 150.

A color filter CF may be provided over the encapsulation layer 150. The color filter CF may be provided over one surface of the second substrate 112 that faces the first substrate 111. In this case, the first substrate 111 provided with the encapsulation layer 150 and the second substrate 112 provided with the color filter CF may be bonded to each other by an adhesive layer. At this time, the adhesive layer may be an optically clear resin (OCR) layer or an optically clear adhesive (OCA) film.

The color filter CF may be provided to be patterned for each of the subpixels SP1, SP2, SP3 and SP4. In detail, the color filter CF may include a first color filter, a second color filter, and a third color filter. The first color filter may be disposed to correspond to the emission area EA1 of the first subpixel SP1, and may be a red color filter that transmits red light. The second color filter may be disposed to correspond to the emission area EA2 of the second subpixel SP2, and may be a green color filter that transmits green light. The third color filter may be disposed to correspond to the emission area EA3 of the third subpixel SP3, and may be a blue color filter that transmits blue light.

A black matrix BM may be provided between color filters CF. The black matrix BM may be disposed between the subpixels SP1, SP2, SP3 and SP4 to prevent a color mixture from occurring between adjacent subpixels SP1, SP2, SP3 and SP4.

Meanwhile, the black matrix BM may at least partially overlap the first connection portions BE1-1, BE2-1, BE3-1 and BE4-1 of the bridge electrode BE. That is, the first bridge area BA1 provided with the first connection portions BE1-1, BE2-1, BE3-1 and BE4-1 of the bridge electrode BE may be disposed in an area in which a black matrix BM is formed. Therefore, the display panel 110 according to one embodiment of the present disclosure may prevent an aperture ratio from being reduced by the first connection portions BE1-1, BE2-1, BE3-1 and BE4-1.

The black matrix BM may include a material that absorbs light, for example, a black dye that absorbs all of the light in a visible wavelength range.

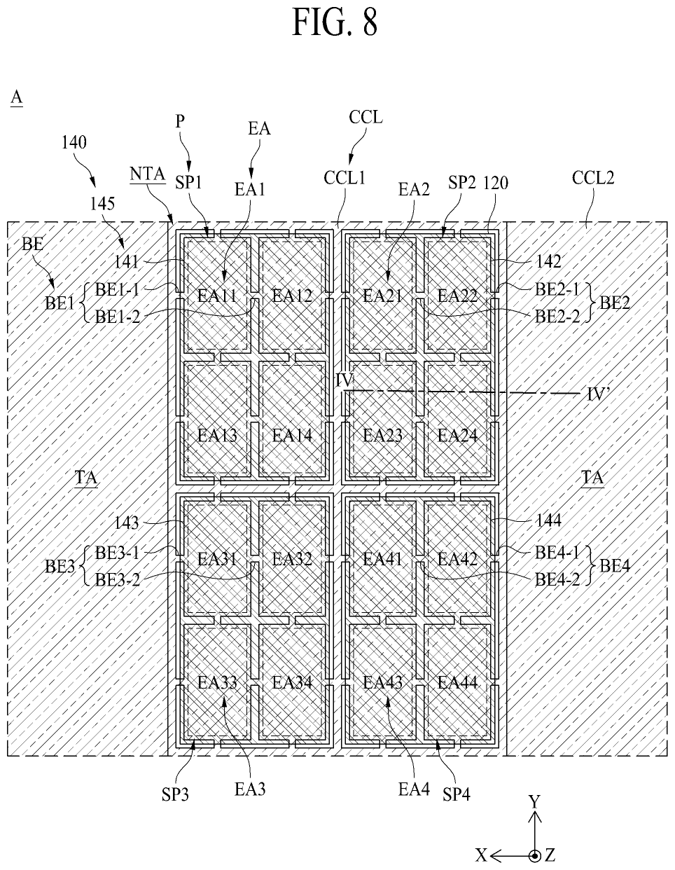

Although the description in FIGS. 2 to 7 is based on that the display panel 110 is a general display panel, the present disclosure is not limited thereto. The second electrode 140 described in FIGS. 2 to 7 may be also applied to a transparent display panel. Hereinafter, pixels of the transparent display panel will be described in detail with reference to FIGS. 8 to 11.

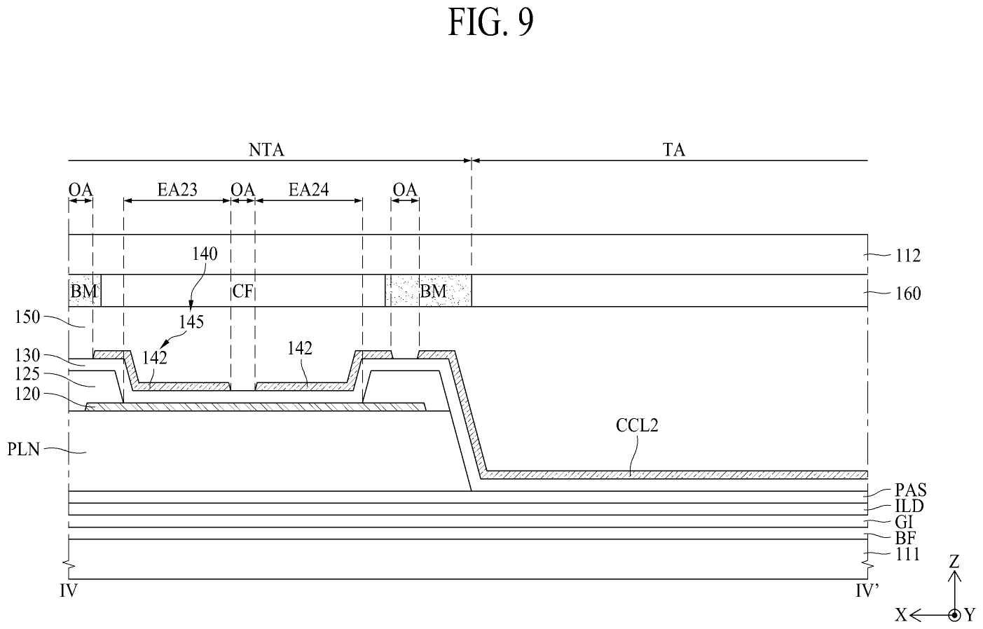

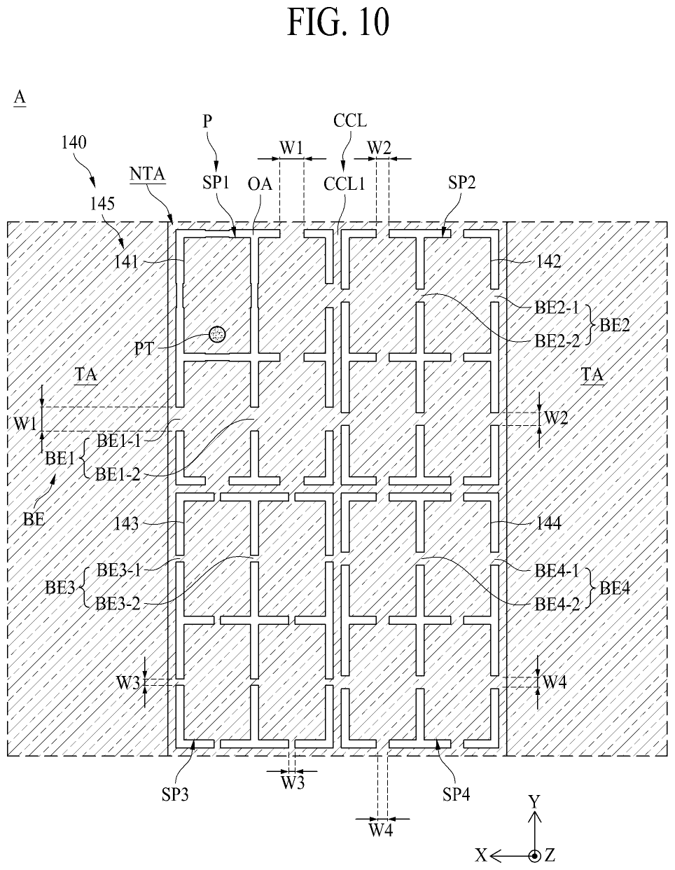

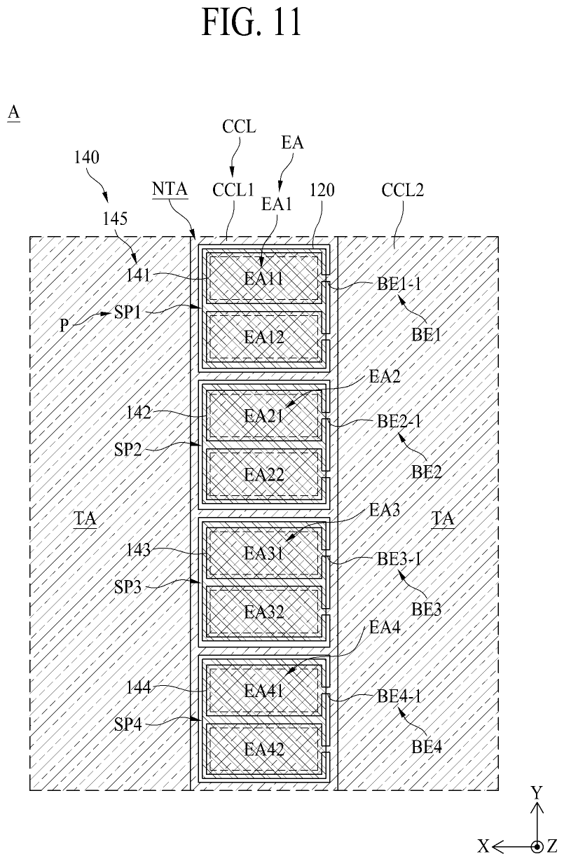

FIG. 8 is a view illustrating another example of a pixel of a display panel shown in FIG. 1, FIG. 9 is a cross-sectional view illustrating an example of line IV-IV′ of FIG. 8, FIG. 10 is a view illustrating an example that particles occur in one of a plurality of divided electrodes in FIG. 8, and FIG. 11 is a view illustrating a modified example of FIG. 8.

The display panel 110 shown in FIGS. 8 to 11 is different from the display panel 110 shown in FIGS. 2 to 7 in that the display panel 110 is a transparent display panel. Hereinafter, the following description will be based on the difference from the display panel 110 shown in FIGS. 2 to 7, and repeated descriptions will be omitted.

Referring to FIGS. 8 to 11, the display area DA may include a transmissive area TA and a non-transmissive area NTA. The transmissive area TA is an area through which most of externally incident light passes, and the non-transmissive area NTA is an area through which most of externally incident light fails to transmit. For example, the transmissive area TA may be an area where light transmittance is greater than α %, for example, about 90%, and the non-transmissive area NTA may be an area where light transmittance is smaller than β %, for example, about 50%. At this time, α is greater than β. A user may view an object or background arranged over a rear surface of the transparent display panel 110 due to the transmissive area TA.

The non-transmissive area NTA may be disposed between the adjacent transmissive areas TA, and may include a plurality of pixels P and a plurality of signal lines. The plurality of signal lines may include scan lines extending in a first direction (X-axis direction) and data lines in a second direction (Y-axis direction) in the non-transmissive area NTA.

Pixels P may be provided between the transmissive areas TA, and emit a predetermined or selected light to display an image. The light emission area EA may correspond to an area, from which light is emitted, in the pixel P.

Each of the pixels P may include at least one of a first subpixel SP1, a second subpixel SP2, a third subpixel SP3 and a fourth subpixel SP4. The first subpixel SP1 may include a first light emission area EA1 emitting light of a red color. The second subpixel SP2 may include a second light emission area EA2 emitting light of a green color. The third subpixel SP3 may include a third light emission area EA3 emitting light of a blue color. The fourth subpixel SP4 may include a fourth light emission area EA4 emitting light of a white color, but is not limited thereto.

Meanwhile, in some embodiments, light emission areas EA1, EA2, EA3 and EA4 respectively provided in a plurality of subpixels P1, P2, P3 and P4 may include light emission areas divided into a plurality of areas. In detail, the first light emission area EA1 provided in the first subpixel SP1 may include four divided areas, that is, a first divided light emission area EA11, a second divided light emission area EA12, a third divided light emission area EA13 and a fourth divided light emission area EA14. The second light emission area EA2 provided in the second subpixel SP2 may include four divided areas, that is, a first divided light emission area EA21, a second divided light emission area EA22, a third divided light emission area EA23 and a fourth divided light emission area EA24. The third light emission area EA3 provided in the third subpixel SP3 may include four divided areas, that is, a first divided light emission area EA31, a second divided light emission area EA32, a third divided light emission area EA33 and a fourth divided light emission area EA34. The fourth light emission area EA4 provided in the fourth subpixel SP4 may include four divided areas, that is, a first divided light emission area EA41, a second divided light emission area EA42, a third divided light emission area EA43 and a fourth divided light emission area EA44.

Each of the plurality of subpixels SP1, SP2, SP3 and SP4 may include a circuit element, which includes at least one transistor and a capacitor, and a light emitting element. The at least one transistor may include a driving transistor TFT, a switching transistor, and a sensing transistor.

In detail, the driving transistor TFT including the active layer ACT, the gate electrode GE, the source electrode SE and the drain electrode DE may be provided over a first substrate 111. A passivation layer PAS for protecting the driving transistor TFT may be provided over the driving transistor TFT. A planarization layer PLN for planarizing a step difference due to the driving transistor TFT may be provided over the passivation layer PAS.

A light emitting element, which includes a first electrode 120, an organic light emitting layer 130 and a second electrode 140, and a bank 125 may be provided over the planarization layer PLN.

The first electrode 120 may be provided for each of the subpixels SP1, SP2, SP3 and SP4 over the planarization layer PLN. The first electrode 120 is not provided in a transmissive area TA. Since the first electrode 120 is substantially the same as the first electrode 120 described in FIGS. 2 to 7, its detailed description will be omitted.

The bank 125 may be provided over the planarization layer PLN. The bank 125 may be provided between the first electrodes 120 provided in each of the first to fourth subpixels SP1, SP2, SP3, and SP4. The bank 125 may be provided to at least partially cover an edge of each of the first electrodes 120 and expose a portion of each of the first electrodes 120. Therefore, the bank 125 may prevent a problem in which light emitting efficiency is deteriorated due to concentration of a current on an end of each of the first electrodes 120.

The bank 125 may define (e.g., laterally surround) light emission areas EA1, EA2, EA3 and EA4 of the subpixels SP1, SP2, SP3 and SP4. The area in which the bank 125 is provided may become the non-light emission area NTA because light is not emitted therefrom, and the area in which the bank 125 is not provided and the first electrode is exposed may become the light emission areas EA1, EA2, EA3 and EA4.

The organic light emitting layer 130 may be provided over the first electrode 120. In one embodiment, the organic light emitting layer 130 may be a common layer in which a light emitting layer is commonly provided in the subpixels SP1, SP2, SP3 and SP4. At this time, the light emitting layer may be a white light emitting layer for emitting white light. In this case, the light emitting layer of the organic light emitting layer 130 may be provided even in the transmissive area TA as shown in FIG. 9.

In another embodiment, the organic light emitting layer 130 may have light emitting layers provided for each of the subpixels SP1, SP2, SP3 and SP4. For example, a red light emitting layer for emitting red light may be provided in the first sub pixel SP1, a green light emitting layer for emitting green light may be provided in the second sub pixel SP2, a blue light emitting layer for emitting blue light may be provided in the third sub pixel SP3, and a white light emitting layer for emitting white light may be provided in the fourth sub pixel SP4. In this case, the light emitting layer of the organic light emitting layer 130 may not be provided in the transmissive area TA.

The second electrode 140 may be provided over the organic light emitting layer 130 and the bank 125. The second electrode 140 may be provided in each of the plurality of subpixels SP1, SP2, SP3 and SP4. The second electrodes 140 respectively provided in the plurality of subpixels SP1, SP2, SP3 and SP4 may be connected to each other through a cathode connection line CCL.

In this case, the cathode connection line CCL may connect the second electrodes 140 formed to be patterned in the plurality of subpixels SP1, SP2, SP3 and SP4 to each other. The cathode connection line CCL may include a first cathode connection line CCL1 and a second cathode connection line CCL2 provided in the transmissive area TA.

The first cathode connection line CCL1 may be provided between the plurality of subpixels SP1, SP2, SP3 and SP4 and extended in the first direction (X-axis direction) or the second direction (Y-axis direction). Alternatively, the first cathode connection line CCL1 may have a lattice shape extended in the first direction (X-axis direction) and the second direction (Y-axis direction) between the plurality of subpixels SP1, SP2, SP3 and SP4 as shown in FIG. 8.

The second cathode connection line CCL2 may be disposed to at least partially overlap the transmissive area TA provided between the pixels P. The second cathode connection line CCL2 may be extended in the first direction (X-axis direction), or may be extended in the second direction (Y-axis direction).

The first cathode connection line CCL1 and the second cathode connection line CCL2 may be provided in the same layer as the second electrode 140 and integrally formed with the second electrode 140 as shown in FIGS. 8 and 9. That is, a portion of one layer may be a cathode connection area (not shown) in which the first cathode connection line CCL1 and the second cathode connection line CCL2 are disposed. In another embodiment, the first cathode connection line CCL1 and the second cathode connection line CCL2 may be provided in a layer different from the second electrode 140, and in this case, the first cathode connection line CCL1 and the second cathode connection line CCL2 may be electrically connected to the second electrode 140 through a contact hole.

Meanwhile, the second electrode 140 provided in each of the plurality of subpixels SP1, SP2, SP3 and SP4 may be comprised of a plurality of divided electrodes 145 and a bridge electrode BE.

Two or more divided electrodes 145 may be provided, and may be spaced apart from each other in the first direction (X-axis direction) or the second direction (Y-axis direction).

In one embodiment, the plurality of divided electrodes 145 may be provided as much as the number of divided light emission areas. For example, as shown in FIG. 8, four divided electrodes 145 may be provided to be equal to the number of divided light emission areas. In this case, the plurality of divided electrodes 145 may be disposed to respectively correspond to the plurality of divided light emission areas. For example, four divided electrodes 141 provided in the first subpixel SP1 may be disposed to correspond to four first divided light emission areas EA11, EA12, EA13 and EA14.

As described above, the four divided electrodes 145 may be provided to be equal to the number of divided light emission areas, but the present disclosure is not limited thereto. Two divided electrodes 145 may be provided, or five or more divided electrodes 145 may be provided. Hereinafter, for convenience of description, the following description will be based on that four divided electrodes are provided.

The bridge electrode BE may connect the plurality of divided electrodes 145 to each other or connect the plurality of divided electrodes 145 with the first cathode connection line CCL1 or the second cathode connection line CCL2.

In detail, the second electrode 140 provided in the first subpixel SP1 may include a plurality of first divided electrodes 141 and a first bridge electrode BE1.

The plurality of first divided electrodes 141 may be disposed to respectively correspond to the plurality of first divided light emission areas EA11, EA12, EA13 and EA14. That is, the plurality of first divided electrodes 141 may at least partially overlap the plurality of first divided light emission areas EA11, EA12, EA13 and EA14, respectively.

In addition, the plurality of first divided electrodes 141 may be spaced apart from each other by an opening area OA formed to expose the organic light emitting layer 130 between the plurality of first divided light emission areas EA11, EA12, EA13 and EA14. Also, the plurality of first divided electrodes 141 may be spaced apart from the cathode connection line CCL.

The first bridge electrode BE1 may include at least one of a first connection portion BE1-1 and a second connection portion BE1-2.

The first connection portion BE1-1 of the first bridge electrode BE1 may be disposed between the plurality of first divided electrodes 141 and the cathode connection line CCL, or between the plurality of first divided electrodes 141 and the transmissive area TA, to connect the plurality of first divided electrodes 141 with the cathode connection line CCL. The first connection portion BE1-1 may be provided in a plural number. Each of the plurality of first connection portions BE1-1 may be disposed between one of the plurality of first divided electrodes 141 and the cathode connection line CCL, such that one end thereof may be connected to one of the plurality of first divided electrodes 141 and the other end thereof may be connected to the cathode connection line CCL.

Therefore, each of the plurality of first divided electrodes 141 may be connected to one or more first connection portions BE1-1, and may be connected to the cathode connection line CCL through one or more first connection portions BE1-1. For example, as shown in FIG. 8, the first divided electrode 141 disposed in the first divided light emission area EA11 may be connected to two first connection portions BE1-1, and may be connected to the cathode connection line CCL through two first connection portions BE1-1. At this time, one of the two first connection portions BE1-1 may be connected to the first cathode connection line CCL1, and the other one thereof may be connected to the second cathode connection line CCL2.

As described above, the plurality of first connection portions BE1-1 are disposed between the first subpixel SP1 and the other subpixels adjacent to the first subpixel SP1 or between the first subpixel SP1 and the transmissive area TA, and thus may at least partially overlap the bank 125.

The second connection portion BE1-2 of the first bridge electrode BE1 may be disposed between the plurality of first divided electrodes 141 to connect the plurality of first divided electrodes 141 to each other. The second connection portion BE1-2 may be provided in a plural number. Each of the plurality of second connection portions BE1-2 may be disposed between two first divided electrodes 141 adjacent to each other, such that one end thereof may be connected to one of the first divided electrodes 141, and the other end thereof may be connected to the other first divided electrode 141.

Therefore, each of the plurality of first divided electrodes 141 may be connected to one or more second connection portions BE1-2, and may be connected to another first divided electrode 141 disposed to be adjacent thereto through one or more second connection portions BE1-2. For example, as shown in FIG. 8, the first divided electrode 141 disposed in the first divided light emission area EA11 may be connected to the two second connection portions BE1-2. The first divided electrode 141 disposed in the first divided light emission area EA11 may be connected to the first divided electrode 141 disposed in the second divided light emission area EA12 and the first divided electrode 141 disposed in the third divided light emission area EA13 through the two second connection portions BE1-2.

As described above, the plurality of second connection portions BE1-2 are disposed between the plurality of first divided light emission areas EA11, EA12, EA13 and EA14, and thus may not overlap the bank 125.

The first and second connection portions BE1-1 and BE2-2 may be formed in the same layer as the first divided electrodes 141, and may be integrally formed with the first divided electrodes 141.

The second electrode 140 provided in the second subpixel SP2 may include a plurality of second divided electrodes 142 and a second bridge electrode BE2, and the second bridge electrode BE2 may include at least one of a first connection portion BE2-1 and a second connection portion BE2-2.

The second electrode 140 provided in the third subpixel SP3 may include a plurality of third divided electrodes 143 and a third bridge electrode BE3, and the third bridge electrode BE3 may include at least one of a first connection portion BE3-1 and a second connection portion BE3-2.

The second electrode 140 provided in the fourth subpixel SP4 may include a plurality of fourth divided electrodes 144 and a fourth bridge electrode BE4, and the fourth bridge electrode BE4 may include at least one of a first connection portion BE4-1 and a second connection portion BE4-2.

The second electrode 140 provided in the second subpixel SP2, the third subpixel SP3 and the fourth subpixel SP4 has a position different from that of the second electrode 140 provided in the first subpixel SP1 but has the substantially same configuration as that of the second electrode 140 provided in the first subpixel SP1. Therefore, the description of the second electrode 140 provided in the first subpixel SP1 may be equally applied to the second electrode 140 provided in the second subpixel SP2, the third subpixel SP3 and the fourth subpixel SP4.

Hereinafter, differences between the second electrodes 140 respectively provided in the first subpixel SP1, the second subpixel SP2, the third subpixel SP3 and the fourth subpixel SP4 will be described, and repeated descriptions will be omitted.

The bridge electrode BE of the second electrode 140 may be provided to have different widths for the respective subpixels SP1, SP2, SP3 and SP4. In this case, the width may represent a length of a side that is in contact with the divided electrode 145.

In detail, in the display panel 110 according to one embodiment of the present disclosure, the width of the bridge electrode BE of the second electrode 140 may be formed differently depending on a limit current of a driving transistor TFT of each of the subpixels SP1, SP2, SP3 and SP4.

A current selected for each of the first to fourth subpixels SP1, SP2, SP3 and SP4 may be different depending on a color of the emitted light. A size of the driving transistor TFT provided in each of the first to fourth subpixels SP1, SP2, SP3 and SP4 may be determined in consideration of the selected current. For example, the current selected for the first subpixel SP1, which emits red light, among the first to fourth subpixels SP1, SP2, SP3 and SP4 may be the largest. In this case, the driving transistor TFT connected to the first electrode 120 of the first subpixel SP1 may have a size greater than that of the driving transistor TFT of each of the second to fourth subpixels SP2, SP3 and SP4 to have a high limit current. As another example, the current selected for the third subpixel SP3, which emits blue light, among the first to fourth subpixels SP1, SP2, SP3 and SP4 may be the smallest. In this case, the driving transistor TFT connected to the first electrode 120 of the third subpixel SP3 may have a size smaller than that of the driving transistor TFT of each of the first, second and fourth subpixels SP1, SP2 and SP4 to have a low limit current.

A magnitude of a current flowing in the bridge electrode BE of the second electrode 140 provided in each of the first to fourth subpixels SP1, SP2, SP3 and SP4 may vary depending on the sizes of the driving transistors TFT. When the size of the driving transistor TFT is large, the current supplied from the driving transistor TFT is large, so that the current flowing through the second electrode 140 may be large. On the other hand, when the size of the driving transistor TFT is small, the current supplied from the driving transistor TFT is small, so that the current flowing through the second electrode 140 may be small.

In the display panel 110 according to one embodiment of the present disclosure, resistance of the bridge electrode BE may be adjusted by adjustment of the width of the bridge electrode BE of the second electrode 140. Therefore, the display panel 110 according to one embodiment of the present disclosure may ensure that the bridge electrode BE connected to the divided electrode 145, in which particles occur, may be melted in each of the first to fourth subpixels SP1, SP2, SP3 and SP4 to separate the bridge electrode BE in which particles occur.

For example, the driving transistor TFT connected to the first electrode 120 of the first subpixel SP1 may be the largest, and the driving transistor TFT connected to the first electrode 120 of the third subpixel SP3 may be the smallest. For example, the driving transistor TFT connected to the first electrode 120 of the red subpixel SP1 may be the largest, and the driving transistor TFT connected to the first electrode 120 of the blue subpixel SP3 may be the smallest.

In this case, a third width W3 of the third bridge electrode BE3 of the second electrode 140 provided in the third subpixel SP3 may be formed to be smaller than a first width W1 of the first bridge electrode BE1 of the second electrode 140 provided in the first subpixel SP1 as shown in FIG. 10. Therefore, the display panel 110 according to another embodiment of the present disclosure may increase resistance of the third bridge electrode BE3 of the third subpixel SP3 even though the driving transistor TFT provided in the third subpixel SP3 has a low limit current. In addition, the display panel 110 according to one embodiment of the present disclosure may generate heat sufficient to melt the third bridge electrode BE3 when a short line occurs between the first electrode 120 and the third divided electrode 143.

For example, in the display panel 110 according to another embodiment of the present disclosure, the width W3 of the bridge electrode BE3 in the blue subpixel SP3 may be the smallest, and the width W1 of the bridge electrode BE1 in the red subpixel SP1 may be the largest.

In the display panel 110 according to another embodiment of the present disclosure, when the current applied from the driving transistor TFT is small, the width of the bridge electrode BE connected to the corresponding driving transistor TFT may be reduced, whereby resistance of the bridge electrode BE may be increased. Therefore, the display panel 110 according to another embodiment of the present disclosure may ensure that the bridge electrode BE, which is in contact with the divided electrode 145 in which particles occur, may be melted when the particles occur, to separate the divided electrode 145, in which particles occur, from the other elements.

The second electrodes 140 respectively provided in the plurality of subpixels SP1, SP2, SP3 and SP4 may be common layers that are electrically connected to each other to apply the same voltage. The second electrodes 140 may be made of a conductive material capable of transmitting light. For example, the second electrodes 140 may be formed of a low resistance metal material such as silver (Ag) or an alloy of magnesium (Mg) and silver (Ag).

In the display panel 110 according to another embodiment of the present disclosure, the second electrode 140 provided in each of the plurality of subpixels SP1, SP2, SP3 and SP4 includes a plurality of divided electrodes 145 and a bridge electrode BE. Therefore, in the display panel 110 according to another embodiment of the present disclosure, even though particles occur in any one of the plurality of divided electrodes 145, only an area in which the corresponding divided electrode is provided may become a dark spot certainly and the other divided electrodes may be normally operated.

In detail, as shown in FIG. 10, in the display panel 110 according to another embodiment of the present disclosure, particles P may occur in any one of the plurality of divided electrodes 145. In this case, in the display panel 110 according to another embodiment of the present disclosure, short may occur between the first electrode 120 and the divided electrode 145 of the second electrode 140 in the area in which the particles are positioned. When an aging signal is applied to the light emitting element during an aging process, a current may be concentrated on the area where the first electrode 120 and the divided electrode 145 of the second electrode 140 are short-circuited.

In the display panel 110 according to another embodiment of the present disclosure, as the current is concentrated on the divided electrode 145 in which particles occur, a large amount of current may flow in the bridge electrode BE that is in contact with the divided electrode 145 in which particles occur. In particular, since the bridge electrode BE is a connection electrode having a width and an area, which are remarkably smaller than those of the divided electrode 145, the bridge electrode BE may have high resistance. Therefore, significant heat may be generated in the bridge electrode BE by Joule heating. As the current is concentrated on the divided electrode 145 in which particles occur, the bridge electrode BE, which is in contact with the divided electrode 145 in which particles occur, may be melted to electrically separate the divided electrode 145, in which particles occur, from the other divided electrodes 145 as shown in FIG. 10.

The display panel 110 according to another embodiment of the present disclosure may disconnect the connection between the divided electrodes 145 in which particles occur and the other divided electrodes 145, thereby emitting light in the area where the divided electrode 145, in which particles do not occur, is provided.

One of methods of allowing the area in which particles occur to become a dark spot is to form the first electrode 120 by the plurality of divided electrodes. Since the first electrode 120 is generally formed of a plurality of layers and is made of a reflective metal material having a high melting point such as Ti, Al, Ag, etc., the first electrode 120 may not be melted even though a high resistance area is formed. For this reason, when particles occur in one of the plurality of divided electrodes constituting the first electrode 120, a connection line connecting the divided electrode, in which particles occur, with the driving transistor TFT may be cut by a laser, so that the divided electrode in which particles occur and the driving transistor TFT may be disconnected from each other.

However, in this method, other lines and peripheral elements may be damaged due to the laser, and it is beneficial that other lines and circuit elements should be designed not to overlap a laser cutting area and thus prevented from being damaged by the laser. In this case, since the lines and the circuit elements should be designed in a limited space, the size of the light emission area EA or the transmissive area TA may be reduced to make sure of the laser cutting area. In addition, since a laser cutting process for searching for a divided electrode in which particles occur and disconnecting the divided electrode in which particles occur from the driving transistor TFT should be added, the process becomes complicated and the process time may be increased.

In the display panel 110 according to another embodiment of the present disclosure, the second electrode 140, which has a relatively low melting point, not the first electrode 120 is formed of the plurality of divided electrodes 145, and the plurality of divided electrodes 145 are connected to each other by the bridge electrode BE having high resistance.

When particles occur in any one of the plurality of divided electrodes 145, as the current is concentrated on the divided electrode 145 in which particles occur, a large amount of current flows in the bridge electrode BE that is in contact with the divided electrode 145 in which particles occur. For example, when particles occur in the first divided electrode 141 disposed in the first divided light emission area EA11 of the first subpixel SP1, as the current is concentrated on the first divided electrode 141 in which particles occur, a large amount of current may flow in the first bridge electrode BE1 that is in contact with the first divided electrode 141 in which particles occur. Therefore, the first bridge electrode BE1 that is in contact with the first division electrode 141 in which particles occur may generate significant heat and be melted by Joule heating.

As a result, in the display panel 110 according to another embodiment of the present disclosure, the divided electrode 141 in which particles occur may be electrically separated from the first divided electrodes 141, which are disposed in the second to fourth divided light emission areas EA12, EA13 and EA14 of the first subpixel SP1, without laser cutting.

Therefore, in the display panel 110 according to another embodiment of the present disclosure, the other lines and circuit elements may be prevented from being damaged by the laser, and since a separate laser cutting process may be omitted, the process may be simplified and the process time may be shortened.

Also, the display panel 110 according to another embodiment of the present disclosure may not reduce the size of the light emission area EA or the transmissive area TA in forming the second electrode 140 to be patterned.

In addition, in the display panel 110 according to another embodiment of the present disclosure, when particles occur, the light emitting layer 130 and the divided electrode 145 of the second electrode 140 in the area in which particles occur are melted or sublimated by Joule heating, so that aging may be primarily performed. In the display panel 110 according to another embodiment of the present disclosure, only the area in which particles occur may locally become a dark spot by primary aging. However, the primary aging may be performed when sufficient heat is not generated in the area in which particles are positioned, or when the divided electrode and the second electrode 140 are electrically connected to each other without being insulated from each other depending on a state that the light emitting layer 130 and the divided electrode 145 of the second electrode 140 are melted.

In this case, in the display panel 110 according to another embodiment of the present disclosure, as the current is still concentrated on the divided electrode 145 in which particles occur, the bridge electrode BE may be melted by Joule heating, whereby aging may be secondarily be performed. Therefore, in the display panel 110 according to another embodiment of the present disclosure, only a portion, in which particles occur, among the subpixels may become a dark spot, whereby the entire subpixels may be prevented from becoming dark spots.

An encapsulation layer 150 may be provided over the light emitting elements. A color filter CF may be provided over the encapsulation layer 150. The color filter CF may be disposed over one surface of the second substrate 112, which faces the first substrate 111. In this case, the first substrate 111 provided with the encapsulation layer 150 and the second substrate 112 provided with the color filter CF may be bonded to each other by a separate adhesive layer 160. The adhesive layer 160 may be an optically clear resin layer (OCR) or an optically clear adhesive film (OCA).

The color filter CF may be provided to be patterned for each of subpixels SP1, SP2, SP3 and SP4, and a black matrix BM may be provided between the color filters CF. The black matrix BM may be provided between the subpixels SP1, SP2, SP3 and SP4 to prevent color mixture from occurring between adjacent subpixels SP1, SP2, SP3 and SP4.

In addition, the black matrix BM may be provided between the color filter CF and the transmissive area TA. The black matrix BM may be disposed between the transmissive area TA and the plurality of subpixels SP1, SP2, SP3 and SP4 to prevent light emitted from each of the plurality of subpixels SP1, SP2, SP3 and SP4 from moving to the transmissive area TA.

The black matrix BM may at least partially overlap the first connection portions BE1-1, BE2-1, BE3-1 and BE4-1 of the bridge electrode BE. That is, the first connection portions BE1-1, BE2-1, BE3-1 and BE4-1 of the bridge electrode BE may be disposed in an area in which the black matrix BM provided between the color filters CF and between the transmissive area TA and the plurality of subpixels SP1, SP2, SP3 and SP4 is formed. Therefore, the display panel 110 according to another embodiment of the present disclosure may prevent an aperture ratio and transmittance due to the first connection portions BE1-1, BE2-1, BE3-1, and BE4-1.

Meanwhile, the display panel 110 illustrated in FIGS. 2 to 10 is illustrated that the second electrode 140 includes four divided electrodes 145, but is not limited thereto.

In another embodiment, the second electrode 140 may include two divided electrodes 145 as shown in FIG. 11. In detail, the first light emission area EA1 provided in the first subpixel SP1 is divided into two and thus may include a first divided light emission area EA11 and a second divided light emission area EA12. The second light emission area EA2 provided in the second subpixel SP2 is divided into two and thus may include a first divided light emission area EA21 and a second divided light emission area EA22. The third light emission area EA3 provided in the third subpixel SP3 is divided into two and thus may include a first divided light emission area EA31 and a second divided light emission area EA32. The fourth light emission area EA4 provided in the fourth subpixel SP4 is divided into two and thus may include a first divided light emission area EA41 and a second divided light emission area EA42.

In the display panel 110, as the number of divided electrodes 145 of the second electrode 140 is increased, the size of the light emission area, which becomes a dark spot when particles occur, may be reduced, but its aperture ratio may be reduced. In consideration of this, the number of divided electrodes 145 of the second electrode 140 in the display panel 110 may be determined. The display panel 110 shown in FIG. 11 may have an aperture ratio higher than that of the display panel 110 shown in FIGS. 2 to 10.

Meanwhile, the display panel 110 shown in FIGS. 2 to 10 illustrates that the bridge electrode BE of the second electrode 140 includes all of the first connection portions BE1-1, BE2-1, BE3-1 and BE4-1 and the second connection portions BE1-2, BE2-2, BE3-2 and BE4-2, but is not limited thereto.

In another embodiment, the bridge electrode BE of the second electrode 140 may include only the first connection portions BE1-1, BE2-1, BE3-1 and BE4-1 as shown in FIG. 11. In detail, the second electrode 140 provided in the first subpixel SP1 may include a plurality of first divided electrodes 141 and a first bridge electrode BE1.

Each of the plurality of first divided electrodes 141 may be disposed to correspond to each of the plurality of first divided light emission areas EA11 and EA12. In addition, the plurality of first divided electrodes 141 may be spaced apart from each other in the first direction (X-axis direction) or the second direction (Y-axis direction). In addition, the plurality of first divided electrodes 141 may be also spaced apart from the cathode connection line CCL.

The first bridge electrode BE1 may include a first connection portion BE1-1. The first connection portion BE1-1 of the first bridge electrode BE1 may be disposed between the plurality of first divided electrodes 141 and the cathode connection line CCL to connect the plurality of first divided electrodes 141 with the cathode connection line CCL. For example, the first connection portion BE1-1 of the first bridge electrode BE1 may be disposed between the plurality of first divided electrodes 141 and the transmissive area TA to connect the plurality of first divided electrodes 141 with the second cathode connection line CCL2.

The second electrode 140 provided in the second subpixel SP2 may include a plurality of second divided electrodes 142 and a second bridge electrode BE2, and the second bridge electrode BE2 may include a first connection portion BE2-1.

The first connection portion BE2-1 of the second bridge electrode BE2 may be disposed between the plurality of second divided electrodes 142 and the cathode connection line CCL to connect the plurality of second divided electrodes 142 with the cathode connection line CCL. For example, the first connection portion BE2-1 of the second bridge electrode BE2 may be disposed between the plurality of second divided electrodes 142 and the transmissive area TA to connect the plurality of second divided electrodes 142 with the second cathode connection line CCL2.

The second electrode 140 provided in the third subpixel SP3 may include a plurality of third divided electrodes 143 and a third bridge electrode BE3, and the third bridge electrode BE3 may include a first connection portion BE3-1.

The first connection portion BE3-1 of the third bridge electrode BE3 may be disposed between the plurality of third divided electrodes 143 and the cathode connection line CCL to connect the plurality of third divided electrodes 143 with the cathode connection line CCL. For example, the first connection portion BE3-1 of the third bridge electrode BE3 may be disposed between the plurality of third divided electrodes 143 with the transmissive area TA to connect the plurality of third divided electrodes 143 with the second cathode connection line CCL2.

The second electrode 140 provided in the fourth subpixel SP4 may include a plurality of fourth divided electrodes 144 and a fourth bridge electrode BE4, and the fourth bridge electrode BE4 may include a first connection portion BE4-1.

The first connection portion BE4-1 of the fourth bridge electrode BE4 may be disposed between the plurality of fourth divided electrodes 144 and the cathode connection line CCL to connect the plurality of fourth divided electrodes 144 with the cathode connection line CCL. For example, the first connection portion BE4-1 of the fourth bridge electrode BE4 may be disposed between the plurality of fourth divided electrodes 144 and the transmissive area TA to connect the plurality of fourth divided electrodes 144 with the second cathode connection line CCL2.

The display panel 110 shown in FIG. 11 has a smaller number of bridge electrodes BE connected to one divided electrode 145 than the display panel 110 shown in FIGS. 2 to 10. As the number of bridge electrodes BE is reduced, the amount of the current flowing to one bridge electrode BE may be increased. Therefore, when particles occur, a temperature of the bridge electrode BE that is in contact with the divided electrode 145 in which particles occur may be faster increased. In the display panel 110 shown in FIG. 11, a melting time of the bridge electrode BE that is in contact with the divided electrode 145 in which particles occur may be reduced as compared with the display panel 110 shown in FIGS. 2 to 10, and as a result, the aging process time may be shortened.

According to the present disclosure, the following advantageous effects may be obtained.

In the present disclosure, the second electrode, which has a relatively low melting point, not the first electrode may be divided into a plurality of divided electrodes, and the plurality of divided electrodes may be connected to the bridge electrode having high resistance, whereby the bridge electrode that is in contact with the divided electrode in which particles occur may be melted when the particles occur. Therefore, in the present disclosure, the divided electrodes in which particles occur may be electrically separated from the other divided electrodes without laser cutting. In the present disclosure, other lines and circuit elements may be prevented from being damaged by the laser, and since a separate laser cutting process maybe omitted, the process may be simplified, and the process time may be shortened.

Also, in the present disclosure, the bridge electrode of the second electrode may be disposed to at least partially overlap the black matrix. Therefore, in the present disclosure, an aperture ratio or transmittance may be prevented from being reduced by the bridge electrode.

In addition, in the present disclosure, the light emitting layer 130 and the divided electrode of the second electrode 140 in the area in which the particles are positioned may be melted or sublimated by Joule heating, so that aging may be primarily performed, and the bridge electrode that is in contact with the divided electrode may be melted by Joule heating so that aging may be secondarily performed. In this way, in the present disclosure, the size of the light emission area that becomes a dark spot through the primary aging and the secondary aging may be reduced, and only the area in which particles occur may certainly become a dark spot.

Further, in the present disclosure, the width of the bridge electrode may be adjusted in consideration of the limit current of the driving transistor of each of the subpixels. Therefore, the present disclosure may ensure that the divided electrode in which particles occur may be electrically separated from the other divided electrodes when the particles occur even though the driving transistor has a low limit current.

It will be apparent to those skilled in the art that the present disclosure described above is not limited by the above-described embodiments and the accompanying drawings and that various substitutions, modifications and variations can be made in the present disclosure without departing from the spirit or scope of the disclosures. Consequently, it is intended that all variations or modifications derived from the meaning, scope and equivalent concept of the claims fall within the scope of the present disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device comprising:
a substrate provided with a display area;
a plurality of subpixels positioned in the display area;
a driving transistor provided over the substrate;
first electrodes respectively provided in the plurality of subpixels, the first electrodes being over the driving transistor;
a light emitting layer provided over the first electrodes;
second electrodes respectively provided in the plurality of subpixels, the second electrodes being over the light emitting layer; and
a cathode connection line provided between the plurality of subpixels,
wherein each of the second electrodes includes:
a plurality of divided electrodes; and
a bridge electrode connecting the plurality of divided electrodes to each other or connecting the plurality of divided electrodes with the cathode connection line.

2. The display device of claim 1, wherein the cathode connection line is provided in the same layer as the second electrodes, and the bridge electrode of the second electrode includes a first connection portion connecting the plurality of divided electrodes with the cathode connection line.

3. The display device of claim 2, further comprising:
color filters provided to respectively correspond to the plurality of subpixels over the second electrodes; and
a black matrix provided between the color filters,
wherein the first connection portion is disposed to at least partially overlap the black matrix.

4. The display device of claim 1, wherein the cathode connection line is provided between the plurality of subpixels.

5. The display device of claim 1, wherein each of the plurality of subpixels includes a plurality of divided light emission areas, and the plurality of divided electrodes are disposed to respectively correspond to the plurality of divided light emission areas.

6. The display device of claim 1, wherein each of the second electrodes further includes an opening area between the plurality of divided electrodes.

7. The display device of claim 1, wherein the plurality of subpixels include a first subpixel emitting light of a first color and a second subpixel emitting light of a second color,
the second electrode provided in the first subpixel includes a plurality of first divided electrodes and a first bridge electrode connecting the plurality of first divided electrodes, and
the second electrode provided in the second subpixel includes a plurality of second divided electrodes and a second bridge electrode connecting the plurality of second divided electrodes.

8. The display device of claim 7, wherein a first width of the first bridge electrode, which is in contact with the first divided electrode, is different from a second width of the second bridge electrode, which is in contact with the second divided electrode.

9. The display device of claim 7, wherein the driving transistor includes a first driving transistor connected to a first electrode of the first subpixel and a second driving transistor connected to a first electrode of the second subpixel,
the first driving transistor has a size greater than that of the second driving transistor, and
a first width of the first bridge electrode is greater than a second width of the second bridge electrode.

10. A display device comprising:
a substrate provided with transmissive areas and a plurality of subpixels disposed between the transmissive areas;
first electrodes respectively provided in the plurality of subpixels over the substrate;
a light emitting layer provided over the first electrodes;
second electrodes respectively provided in the plurality of subpixels over the light emitting layer; and
a cathode connection line provided in the transmissive areas,
wherein each of the second electrodes includes:
a plurality of divided electrodes; and
a bridge electrode connecting the plurality of divided electrodes to each other or connecting the plurality of divided electrodes with the cathode connection line.

11. The display device of claim 10, wherein the cathode connection line is provided in the same layer as the second electrodes, and the bridge electrode of the second electrode includes a first connection portion provided between the plurality of divided electrodes and the transmissive area to connect the plurality of divided electrodes with the cathode connection line.

12. The display device of claim 11, further comprising:
color filters provided to respectively correspond to the plurality of subpixels over the second electrodes; and
a black matrix provided between the color filters and between the color filter and the transmissive area,
wherein the first connection portion is disposed to at least partially overlap the black matrix provided between the color filter and the transmissive area.

13. The display device of claim 10, wherein the cathode connection line is further provided between the plurality of subpixels.

14. The display device of claim 10, wherein the plurality of divided electrodes are disposed to be spaced apart from the cathode connection line.

15. The display device of claim 10, wherein the plurality of subpixels includes a first subpixel emitting light of a first color and a second subpixel emitting light of a second color,
the second electrode provided in the first subpixel includes a plurality of first divided electrodes and a first bridge electrode connecting the plurality of first divided electrodes with the cathode connection line,
the second electrode provided in the second subpixel includes a plurality of second divided electrodes and a second bridge electrode connecting the plurality of second divided electrodes with the cathode connection line.

16. The display device of claim 15, wherein a first width of the first bridge electrode, which is in contact with the first divided electrode, is different from a second width of the second bridge electrode, which is in contact with the second divided electrode.

17. The display device of claim 15, wherein the driving transistor includes a first driving transistor connected to a first electrode of the first subpixel and a second driving transistor connected to a first electrode of the second subpixel,
the first driving transistor has a size greater than that of the second driving transistor, and
a first width of the first bridge electrode is greater than a second width of the second bridge electrode.

18. A method, comprising:
forming a second electrode layer on a light emitting layer over a substrate;
forming a plurality of divided electrodes and a plurality of connecting portions by forming openings in the second electrode layer; and
isolating one divided electrode from others of the plurality of divided electrodes by removing at least four connection portions of the plurality of connecting portions.

19. The method of claim 18, wherein the removing at least four connection portions comprises melting the at least four connection portions by Joule heating.

20. The method of claim 19, wherein the melting comprises applying a reverse bias voltage to a light emitting element that includes the one divided electrode.
